(19) United States
(12) Patent Application Publication
(10) Pub. No.: US 2006/0104452 A1
(43) Pub. Date: May 18, 2006

(54) Method and apparatus to automatically set speaker modes in a multi-channel speaker system

(76) Inventor: Yong-Jun Park, Seoul (KR)

Correspondence Address: STANZIONE & KIM, LLP, 919 18TH STREET, N.W., SUITE 440, WASHINGTON, DC, 20006, US

(21) Appl. No.: 11/159,175

(22) Filed: Jun. 23, 2005

(30) Foreign Application Priority Data
Nov. 18, 2004 (KR) 2004-94589

(51) Int. Cl. H04R 29/00; H03G 5/00

(52) U.S. Cl. 381/59; 381/58; 381/98

(57) ABSTRACT

A method and apparatus to automatically set a speaker mode based on characteristics of a speaker installed in an audio/video system. The method includes generating a predetermined broadband signal and reproducing the predetermined broadband signal through a speaker, determining a reproducing ability of the speaker for each frequency band by analyzing frequency characteristics of the predetermined broadband signal reproduced through the speaker, and setting the speaker mode of the speaker based on the determined reproducing ability of the speaker.

### CROSS-REFERENCE TO RELATED APPLICATIONS

This application claims priority from Korean Patent Application No. 2004-94589, filed on Nov. 18, 2004, in the Korean Intellectual Property Office, the disclosure of which is incorporated herein in its entirety by reference.

### BACKGROUND OF THE INVENTION

1. Field of the Invention

The present general inventive concept relates to a multi-channel speaker system, and more particularly, to a method and apparatus to automatically set a speaker mode based on characteristics of a speaker installed in an audio and/or video system.

2. Description of the Related Art

A typical home theater system includes a 5.1 channel amplifier, a digital versatile disc (DVD) playback device, and a tuner, and is used with a large screen digital TV. The system can produce a high quality image using a progressive scan function and can convert a 2-channel stereo sound from a video cassette recorder (VCR) or TV broadcast into 5.1 channel sound using Dolby prologic decoding technology.

However, the home theater system requires a user to manually set speaker modes based on the number of speakers and the frequency response of the speakers in the system.

FIG. 1 is a diagram illustrating a conventional digital signal processor for controlling signal flow according to a manual speaker mode setting in an audio/video system.

Referring to FIG. 1, a front channel, a center channel, a surround channel, a surround back channel, and a low frequency effect (LFE) channel are output to corresponding speakers. Here, a user sets speaker modes by selecting keys mounted on a remote control or a front panel of the audio/video system. The user selects between two speaker modes of “Yes” or “No” with respect to a subwoofer and three speaker modes of “Large,” “Small,” and “None” with respect to the other speakers, based on the number and type of speakers. In the Large mode, all audio signals in an audible frequency band (20 Hz to 20 KHz) are output to the speaker. In the Small mode, middle frequency band signals and high frequency band signals are output to the speaker while low frequency band signals are output to the subwoofer or another speaker. In the None mode, no signal is output to the speaker.

In the “Yes” mode, the low frequency band signals are output to the subwoofer (i.e., “Yes” refers to a subwoofer mode), and in the “No” mode, the low frequency band signals are not output to the subwoofer but are instead output to a front speaker or another speaker.

When the speaker modes are set according to the selection of the user, the digital signal processor uses appropriate low pass filters (LPFs) or high pass filters (HPFs), combines the signals based on the set speaker modes, processes input sound to match each speaker mode, and outputs the processed sound to the corresponding speakers.

In the conventional signal processor in which the speaker modes are set by the user, the conventional signal processor only controls the activation of the LPFs and HPFs, and does not determine whether the speakers are actually connected properly. Additionally, since the user is required to directly set the speaker modes, it is difficult and burdensome to set up a plurality of speakers. Since the speaker modes are set according to a guess made by the user, it is likely that frequency characteristics of the speakers will not correctly match the proper frequency band signals. Accordingly, it is difficult to obtain an optimal sound effect. For example, while a system generates a low frequency signal, a speaker installed in the audio/video system may not be able to reproduce the low frequency signal. Thus, the low frequency signal may be lost. Additionally, if a speaker mode is set to the Large or Small mode, but no corresponding speaker is actually connected to the audio/video system, the user cannot hear the corresponding sound.

### SUMMARY OF THE INVENTION

The present general inventive concept provides a method of automatically setting a speaker mode by determining characteristics of a speaker installed in an audio and/or video system.

The present general inventive concept also provides an apparatus to automatically set a speaker mode by determining the characteristics of a speaker installed in a system.

Additional aspects and advantages of the present general inventive concept will be set forth in part in the description which follows and, in part, will be obvious from the description, or may be learned by practice of the general inventive concept.

The foregoing and/or other aspects and advantages of the present general inventive concept may be achieved by providing a method of automatically setting a speaker mode in a multi-channel speaker system, the method comprising generating a predetermined broadband signal and reproducing the predetermined broadband signal through a speaker, determining a reproducing ability of the speaker for each frequency band by analyzing frequency characteristics of the broadband signal reproduced through the speaker, and setting the speaker mode of the speaker based on the determined reproducing ability of the speaker.

The foregoing and/or other aspects and advantages of the present general inventive concept may also be achieved by providing an apparatus to set a speaker mode in an audio and/or video system having a plurality of channels, comprising an amplifier to amplify a signal, a speaker to reproduce the amplified signal received from the amplifier, a digital signal processor to generate a predetermined broadband signal, to output the predetermined broadband signal to the amplifier, to analyze frequency characteristics of the predetermined broadband signal reproduced through the speaker, and to set the speaker mode of the speaker based on the analyzed frequency characteristics of the speaker, and a microprocessor to receive information about the speaker mode set by the digital signal processor and to control filtering and channel combinations based on the set speaker mode.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a diagram illustrating a conventional digital signal processing block for controlling signal flow according to a manual speaker mode setting in an audio/video system;

FIG. 2 is a block diagram illustrating an apparatus to automatically set a speaker mode in a multi-channel speaker system according to an embodiment of the present general inventive concept;

FIG. 3 is a flowchart illustrating a method of automatically setting a speaker mode in a multi-channel speaker system according to an embodiment of the present general inventive concept;

FIG. 4 illustrates a first example of a signal processing block to automatically set a speaker mode according to an embodiment of the present general inventive concept; and

FIG. 5 illustrates a second example of the signal processing block to automatically set a speaker mode according to an embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

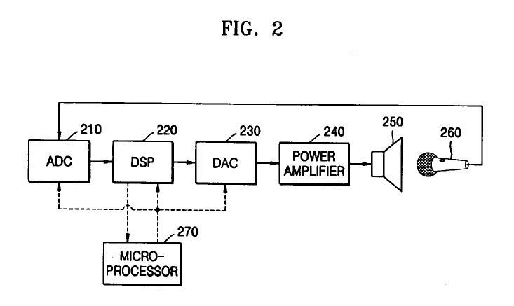

FIG. 2 is a block diagram illustrating an apparatus to automatically set a speaker mode in a multi-channel speaker system according to an embodiment of the present general inventive concept.

Referring to FIG. 2, the apparatus includes an analog-to-digital converter (ADC) 210, a digital signal processor (DSP) 220, a digital-to-analog converter (DAC) 230, a power amplifier 240, a speaker 250, a microphone 260, and a microprocessor 270.

The power amplifier 240 amplifies a broadband signal and outputs the amplified broadband signal to the speaker 250.

The speaker 250 reproduces sound from the amplified broadband signal.

The microphone 260 converts the sound reproduced by the speaker 250 to an electrical signal.

The ADC 210 converts the electrical signal received from the microphone 260 to a digital signal. The DAC 230 converts a digital broadband signal generated by the DSP 220 to an analog broadband signal.

The DSP 220 generates the digital broadband signal, such as white noise, outputs the digital broadband signal to the DAC 230. The digital broadband signal generated by the DSP 220 may be a predetermined signal, such as a test signal (e.g., a white noise signal or an impulse noise signal). The DAC 230 converts the digital broadband signal to the analog broadband signal and outputs the analog broadband signal to the amplifier 240. The DSP 220 also analyzes frequency characteristics of the digital signal received from the ADC 210, determines a reproducing ability of the speaker 250 for each frequency band, and sets a speaker mode for the speaker 250 based on the determined reproducing ability of the speaker 250. The DSP 220 then outputs an output signal that is suitable for the frequency characteristics of the speaker 250 by switching a plurality of channel signals through one or more filters and selecting and combining ones of the plurality of channel signals according to a speaker mode control signal received from the microprocessor 270.

The microprocessor 270 receives information about the set speaker mode from the DSP 220 and outputs to the speaker mode control signal to the DSP 220 to control the filtering and the channel selection/combination.

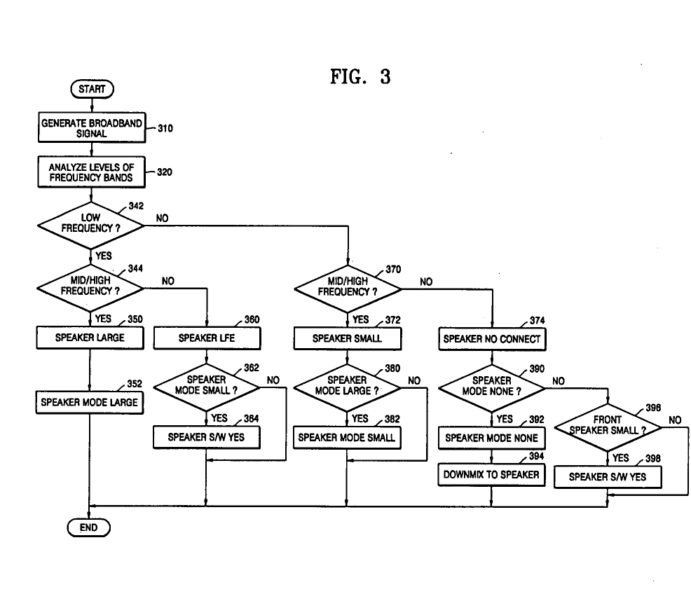

FIG. 3 is a flowchart illustrating a method of automatically setting a speaker mode in a multi-channel speaker system according to an embodiment of the present general inventive concept. The method is described below with reference to the apparatus of FIG. 2. An audio and/or video system (i.e., the multi-channel system) may include a subwoofer (S/W) to output a low frequency effect (LFE) channel, a front speaker to output a front channel, a center speaker to output a center channel, one or more surround speakers to output one or more surround channels, and a surround back speaker to output a surround back channel. Other speakers and/or channels may also be included in the system. Alternatively, the system may include a number of speakers and/or channels that are less than the speakers and channels described above. Each speaker in the system can have a speaker mode and the subwoofer has a subwoofer mode. When the speakers in the system are set to Small, the subwoofer can output low frequency components of channels (other than the LFE channel) that correspond to the other speakers when the subwoofer mode is set to “Yes.” If the subwoofer mode is set to “No,” the subwoofer only outputs the LFE channel and does not output the low frequency components of the channels correspond to the other speakers. When the other speakers in the system are set to Large and the subwoofer mode is set to “Yes,” both the other speakers and the subwoofer output the low frequency components of the channels that correspond to the other speakers. When the subwoofer mode is set to “No,” the subwoofer only outputs the LFE channel. Thus, the embodiments of the present general inventive concept determine reproducibility of frequency bands for the speakers and subwoofer and switch channel signals to prevent any frequency components of the channels from being lost.

Referring to FIG. 3, in operation 310, a broadband signal including a low frequency (e.g., white noise or impulse noise) is generated and output to the speaker 250 in response to a speaker mode set command. The speaker mode set command may be input by a user or may be input automatically when the audio and/or video system is turned on. The DSP 220 has frequency characteristic information of the broadband signal (i.e., it is predetermined and the frequency characteristic information may be stored).

The broadband signal that is reproduced by the speaker 250 is input to the microphone 260.

The frequency characteristics of the broadband signal reproduced through the speaker 250 (e.g., levels of all frequency bands) are analyzed in operation 320. The analyzed levels of the frequency bands of the broadband signal can be tabulated.

A speaker mode is set by determining a frequency reproducing ability of the speaker 250 based on a frequency band level table. The method of automatically setting the speaker mode based on the frequency characteristics of the speaker 250 will now be described with reference to operations 342 through 398.

In operation 342, it is determined whether the broadband signal reproduced through the speaker 250 includes the low frequency component. For example, the broadband signal that is reproduced is checked for a component of less than 1 KHz and −20 dB.

If the broadband signal reproduced through the speaker 250 includes the low frequency component, it is determined whether the broadband signal includes a middle frequency component and a high frequency component in operation 344. If the broadband signal includes all of the low, middle, and high frequency components, the speaker 250 is determined to be able to reproduce all of the frequency bands, in operation 350, and the speaker mode of the speaker 250 is set to “Large” in operation 352. If the broadband signal includes only the low frequency component, the speaker 250 is determined to be able to reproduce only the low frequency band, in operation 360. Accordingly, the speaker 250 is determined to be a subwoofer at operation 360. If a speaker mode of the front speaker is “Small” (i.e., the front speaker outputs the middle and high frequency band), the subwoofer is reset to a subwoofer mode “Yes,” in operations 362 and 364 such that the subwoofer can output low frequency components of the front channel. Additionally, if any one of the speaker modes of other speakers that receive a center channel and surround channels is “Small,” the subwoofer mode is reset to “Yes” such that the subwoofer can output the low frequency components of those channels. If the speaker modes of all other speakers except the subwoofer are “Large,” it is determined whether a signal is input to the subwoofer. If a signal is determined to be input to the subwoofer, the subwoofer mode is reset to “Yes.” Otherwise, the subwoofer mode can be maintained as (or set to) “No,” since the subwoofer only outputs the LFE channel.

If the broadband signal reproduced through the speaker 250 does not include the low frequency component, it is determined whether the broadband signal includes the middle and high frequency components in operation 370. If the broadband signal includes the middle and high frequency components, the speaker 250 is determined to be able to reproduce only the middle and high frequency bands, in operation 372. If the speaker mode of the speaker 250 is set to “Large” in operation 380, the speaker mode is then reset (i.e., changed) to “Small” in operation 382. Accordingly, the low frequency component of a channel signal received at the speaker 250 can then be redirected to the subwoofer by changing the speaker mode of the speaker 250 to “Small.” Additionally, if the broadband signal reproduced through the speaker 250 includes None of the low, middle, and high frequency components, in operation 370, it is determined that the speaker 250 is not connected at all, in operation 374. If the speaker mode of the speaker 250 is set to “None” in operation 390, the speaker mode is not changed in operation 392, and the channel signal output to the speaker 250 is mixed with another channel in operation 394. If the speaker mode of the speaker 250 is not set to “None” in operation 390, and if the speaker mode of the front speaker is set to “Small” in operation 396, the subwoofer mode of the subwoofer is reset to “Yes” in operation 398. Since the front speaker is typically set to the Large speaker mode to output all frequency components, low frequency components of a front channel and other channels that are mixed with the front channel may not be output by the front speaker, when the corresponding speaker mode is set to Small. Accordingly, the subwoofer mode of the subwoofer can be set to “Yes” such that the low frequency components of the front channel and other channels that are mixed with the front channel can be further mixed with a low frequency effect channel (LFE) and output through the subwoofer. For example, when the speaker 250 is determined to be in the None mode, a corresponding channel is mixed with the front channel and is output to the front speaker. When the front speaker is set to Small, any low frequency components can not be output through the front speaker. Thus, operation 398 sets the subwoofer mode to “Yes.”

Finally, if speaker modes of all speakers are set, the filtering and channel combinations are switched based on the set speaker modes.

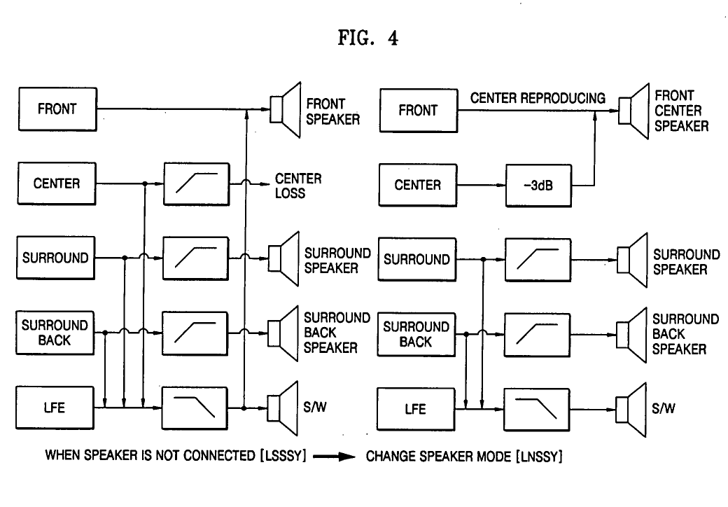

FIG. 4 illustrates a first example of a signal processing block to automatically set a speaker mode according to an embodiment of the present general inventive concept.

Referring to FIG. 4, when the speaker modes of a front speaker, a center speaker, a surround speaker, a surround back speaker, and a subwoofer are respectively set to “Large,” “Small,” “Small,” “Small,” and “Yes,” and if it is assumed that the center speaker is not connected, a center channel signal is lost, since the speaker mode of the center speaker is set to “Small.” In other words, the signal processing block outputs the center channel signal to the center speaker, which is not connected.

However, according to the present embodiment of the present general inventive concept, the speaker modes are automatically set to “Large,” “None,” “Small,” “Small,” and “Yes,” respectively. Therefore, by automatically determining the speaker mode of the center speaker as “None,” the center channel signal can be mixed into a front channel signal and output to the front speaker.

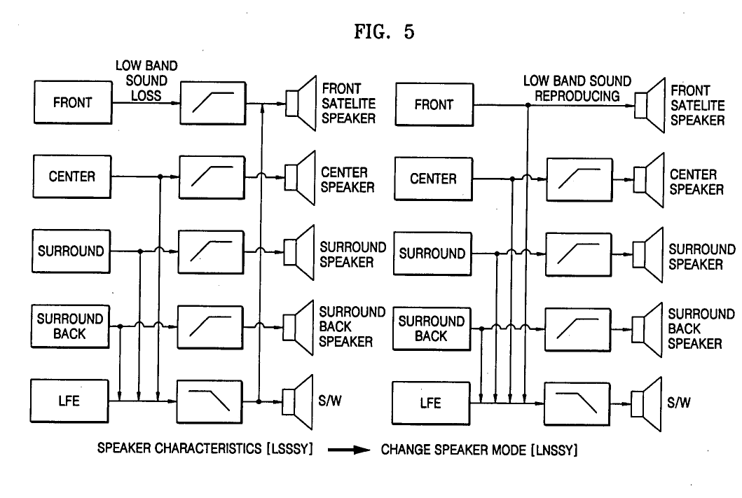

FIG. 5 illustrates a second example of the signal processing block to automatically set a speaker mode according to an embodiment of the present general inventive concept.

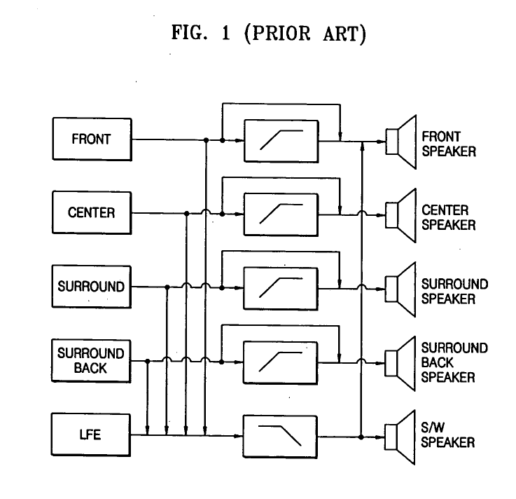

Referring to FIG. 5, it is assumed that the speaker modes of a front satellite speaker, a center speaker, a surround speaker, a surround back speaker, and a subwoofer are respectively set to “Large,” “Small,” “Small,” “Small,” and “Yes”. Here, the front satellite speaker may not be able to properly reproduce low frequency signals. Therefore, in the conventional digital signal processor of FIG. 1, the low frequency signal in a front channel would be lost, since the speaker mode of the front satellite speaker is set to “Large.”

However, according to the present embodiment of the general inventive concept, the speaker modes are automatically set to “Small,” “Small,” “Small,” “Small,” and “Yes,” respectively. Therefore, by automatically determining the speaker mode of the front satellite speaker as “Small,” the low frequency signal of the front channel is mixed into a subwoofer channel signal (i.e., the LFE channel signal) and output to the subwoofer instead of being provided to the front satellite speaker. Although the various embodiments of the present general inventive concept describe specific speaker modes including the Large, Small, None, “Yes,” and “No” speaker and subwoofer modes, it should be understood that the present general inventive concept is not limited to these speaker modes. In particular, the embodiments of the present general inventive concept are more generally directed to providing a plurality of channels and/or portions thereof to speakers that are determined to be appropriate for the plurality of channels and/or portions thereof and setting speaker modes, accordingly. Additionally, although the embodiments of the present general inventive concept are described herein with reference to an audio and/or video system, it should be understood that the embodiments of the present general inventive concept may be used in an audio system without a video component.

The embodiments of the present general inventive concept can be embodied in computer programs and can be implemented in general-use digital computers that execute the programs using a computer readable recording medium. Examples of the computer readable recording medium include magnetic storage media (e.g., ROM, floppy disks, hard disks, etc.), optical recording media (e.g., CD-ROMs, DVDs, etc.), and storage media such as carrier waves (e.g., transmission through the internet). The computer readable recording medium can also be distributed over network coupled computer systems so that the computer programs are stored and executed in a distributed fashion.

As described above, according to embodiments of the present general inventive concept, by detecting the characteristics of speakers and automatically setting speaker modes in a multi-channel audio/video system, the sound of all of audio frequency bands can be heard without loss, convenience is provided to a user who is not familiar with speaker mode setting, and optimal sound can be reproduced by preventing user errors in setting the speaker modes.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A method of automatically setting a speaker mode in a multi-channel speaker system, the method comprising:
generating a predetermined broadband signal and reproducing the broadband signal through a speaker;
determining a reproducing ability of the speaker for each frequency band by analyzing frequency characteristics of the predetermined broadband signal reproduced through the speaker; and
setting the speaker mode of the speaker based on the determined reproducing ability of the speaker.

2. The method of claim 1, wherein the predetermined broadband signal comprises one of a test white noise signal and a test impulse noise signal.

3. The method of claim 1, wherein the setting of the speaker mode of the speaker comprises setting the speaker mode to one of a Small mode, a Large mode, a None mode, a subwoofer “Yes” mode, and a subwoofer “No” mode.

4. The method of claim 1, wherein the multi-channel speaker system comprises a plurality of speakers having a plurality of corresponding speaker modes to determine frequency components provided to the plurality of speakers and at least one subwoofer having a subwoofer mode, and the determining of the reproducing ability comprises determining whether any low frequency components of channels other than a low frequency effect channel are provided to the at least one subwoofer.

5. The method of claim 1, wherein the setting of the speaker mode comprises setting the speaker mode of the speaker as one of a Large speaker mode, a Small speaker mode, and a None speaker mode when the speaker is capable of reproducing all frequency components, mid/high frequency components, and no frequency components, respectively.

6. The method of claim 5, wherein the setting of the speaker mode further comprises:
setting a subwoofer mode such that a subwoofer receives a low frequency component of a channel that corresponds to the speaker, when the speaker mode is set to the Small speaker mode; and
mixing the mid/high frequency components and the low frequency component of the channel that corresponds to the speaker with another channel, when the speaker mode is set to the None speaker mode.

7. The method of claim 1, wherein the determining of the reproducing ability of the speaker comprises detecting whether the speaker is properly connected in the multi-channel system, and the setting of the speaker mode comprises re-directing at least a portion of a channel that is provided to the speaker to an other speaker when the speaker is not properly connected.

8. The method of claim 1, wherein the determining of the reproducing ability of the speaker comprises:
analyzing levels of frequency bands of the predetermined broadband signal;
tabulating the analyzed frequency band levels of the predetermined broadband signal; and
determining the reproducing ability of the speaker based on the tabulated frequency band levels.

9. The method of claim 1, wherein the setting of the speaker mode comprises:
determining a first speaker mode if the predetermined broadband signal includes low and mid/high frequency components;
determining a second speaker mode if the predetermined broadband signal includes only the mid/high frequency component;
determining a third speaker mode if the predetermined broadband signal includes only a low frequency component; and
determining a fourth speaker mode if the predetermined broadband signal includes no frequency components.

10. The method of claim 9, wherein the determining the second speaker mode comprises outputting a mid and high frequency signal of a corresponding channel to the speaker and redirecting a low frequency signal of the corresponding channel to a subwoofer.

11. The method of claim 9, wherein the determining of the fourth speaker mode comprises determining that the speaker is not connected and mixing a sound signal of a corresponding channel provided to the speaker with another channel.

12. A method of automatically setting speaker modes for a plurality of speakers having a plurality of corresponding channels in an audio system, the method comprising:
producing a predetermined broadband signal from the plurality of speakers;
processing frequency characteristics of the plurality of speakers using the produced broadband signal;
setting speaker modes for the plurality of speakers according to the frequency characteristics thereof; and
setting a subwoofer to receive low frequency components of any of the corresponding channels having low frequency components that can not be output by the corresponding speakers.

13. The method of claim 11, wherein the setting of the speaker modes comprises correcting set speaker modes that do not match the corresponding speakers.

14. A method of a speaker mode setting apparatus, the method comprising:
analyzing frequency characteristics of a plurality of speakers to determine frequency components that are reproducible by the plurality of speakers;
determining whether current speaker mode settings match the analyzed frequency characteristics; and
re-setting speaker modes for ones of the plurality of speakers having current speaker settings that do not match the analyzed frequency characteristics.

15. A method of a speaker mode setting apparatus, the method comprising:
providing a first signal to be reproduced through a first speaker;
providing a second signal to be reproduced through a second speaker;
determining a status of the first speaker; and
providing at least a portion of the first signal to the second speaker according to the status of the first speaker so that the at least a portion of the first signal and the second signal are reproduced through the second speaker.

16. An apparatus to a speaker mode in an audio/video system having a plurality of channels, the apparatus comprising:
an amplifier to amplify a signal;
a speaker to reproduce the amplified signal received from the amplifier;
a digital signal processor to generate a predetermined broadband signal, to output the predetermined broadband signal to the amplifier, to analyze frequency characteristics of the predetermined broadband signal reproduced through the speaker, and to set the speaker mode of the speaker based on the analyzed frequency characteristics of the speaker; and
a microprocessor to receive information about the speaker mode set by the digital signal processor and to control filtering and channel combinations based on the information about the set speaker mode.

17. The apparatus of claim 16, wherein the digital signal processor comprises:
means for generating the predetermined broadband signal and for outputting the predetermined broadband signal to the speaker;
means for analyzing the frequency characteristics of the predetermined broadband signal reproduced through the speaker and for tabulating the levels of frequency bands of the predetermined broadband signal;
means for setting the speaker mode of the speaker based on the frequency band levels; and
means for switching filters and channel combinations based on the set speaker mode.

18. The apparatus of claim 16, wherein the digital signal processor detects whether the speaker is properly connected in the audio/video system and re-directs at least a portion of a channel that is provided to the speaker to an other speaker when the speaker is not properly connected.

19. The apparatus of claim 16, wherein the digital signal processor comprises:
a signal generating unit to generate the predetermined broadband signal and to output the predetermined broadband signal to the speaker;
an analyzing unit to analyze the frequency characteristics of the predetermined broadband signal reproduced through the speaker and to tabulate the levels of frequency bands of the predetermined broadband signal;
a setting unit to set the speaker mode of the speaker based on the frequency band levels; and
a switching unit to switch filters and channel combinations based on the set speaker mode.

20. The apparatus of claim 16, wherein the predetermined broadband signal comprises one of a test white noise signal and a test impulse noise signal.

21. The apparatus of claim 16, wherein the digital signal processor sets the speaker mode to one of a Small mode, a Large mode, a None mode, a subwoofer “Yes” mode, and a subwoofer “No” mode.

22. The apparatus of claim 16, wherein the multi-channel system comprises one of a 7.1 channel system and a 5.1 channel system, and includes a plurality of speakers having a plurality of corresponding speaker modes to determine frequency components provided to the plurality of speakers and at least one subwoofer having a subwoofer mode to determine whether any low frequency components of channels other than a low frequency effect channel are provided to the at least one subwoofer.

23. The apparatus of claim 16, wherein the digital signal processor sets the speaker mode of the speaker as one of a Large speaker mode, a Small speaker mode, and a None speaker mode when the speaker is capable of reproducing all frequency components, mid/high frequency components, and no frequency components, respectively.

24. The apparatus of claim 21, wherein the digital signal processor further sets a subwoofer mode such that a subwoofer receives a low frequency component of a channel that corresponds to the speaker, when the speaker mode is set to the Small speaker mode, and mixes the mid/high frequency components and the low frequency components of the channel that corresponds to the speaker with another channel, when the speaker mode is set to the None speaker mode.

25. An apparatus to automatically set speaker modes in an audio system having a plurality of speakers to receive a plurality of channels, comprising:
a digital signal processor to detect frequency characteristics of the plurality of speakers having the plurality of corresponding channels, to set speaker modes for the plurality of speakers according to the frequency characteristics thereof, and to switch and combine the corresponding channels and portions thereof according to the set speaker modes such that no frequency components of the corresponding channels are lost.

26. The apparatus of claim 25, wherein the digital signal processor sets a subwoofer to receive low frequency components of any of the channels having low frequency components that can not be output by the corresponding speakers.

27. The apparatus of claim 25, further comprising:
a detector to detect a predetermined signal including a plurality of frequency components output by a selected speaker; and
an A/D converter to convert the detected signal into a digital detected signal,
wherein the digital signal processor analyzes the digital detected signal to determine the frequency characteristics of the selected speaker.

28. The apparatus of claim 25, wherein the digital signal processor corrects set speaker modes that do not match the frequency characteristics of the corresponding speakers.

29. The apparatus of claim 25, wherein the digital signal processor sets the speaker mode in response to one of a command received from a user and a command generated when the audio system is turned on.

30. An apparatus to set a speaker mode, comprising:
a measuring unit to measure frequency characteristics of at least one speaker over a plurality of frequency bands;
a setting unit to set the speaker mode of the at least one speaker according to frequency bands that are reproducible by the at least one speaker; and
a processing unit to output frequency bands that are reproducible by the at least one speaker to the at least one speaker and to output frequency bands that are not reproducible by the at least one speaker to another speaker.

31. The apparatus of claim 30, wherein the processing unit comprises one or more filters to filter a plurality of channels that correspond to a plurality of speakers and to combine ones of the plurality of channels according to the set speaker mode.

32. An apparatus to set a speaker mode, comprising:
a first processor to provide a first signal to be reproduced through a first speaker and a second signal to be reproduced through a second speaker; and
a second processor to determine a status of the first speaker, and to provide at least a portion of the first signal to the second speaker according to the status of the first speaker so that the at least a portion of the first signal and the second signal are reproduced through the second speaker.

33. A computer readable medium containing executable code to automatically set a speaker mode in a multi-channel speaker system, the medium comprising:
a first executable code to generate a predetermined broadband signal and to reproduce the broadband signal through a speaker;
a second executable code to determine a reproducing ability of the speaker for each frequency band by analyzing frequency characteristics of the predetermined broadband signal reproduced through the speaker; and
a third executable code to set the speaker mode of the speaker based on the determined reproducing ability of the speaker.
